(19) United States
(12) Patent Application Publication
(10) Pub. No.: US 2004/0052969 A1
(43) Pub. Date: Mar. 18, 2004

(54) Methods for operating a chemical vapor deposition chamber using a heated gas distribution plate

(75) Inventors: Ju-Hyung Lee, San Jose, CA (US); Troy Kim, Mountain View, CA (US); Soovo Sen, Sunnyvale, CA (US); Juan Carlos Rocha-Alvarez, Sunnyvale, CA (US); Lun Tsuei, Mountain View, CA (US); Annamalai Lakshmanan, Santa Clara, CA (US); Maosheng Zhao, Santa Clara, CA (US); Inna Shmurun, Foster City, CA (US); Shankar Venkataraman, Santa Clara, CA (US)

Correspondence Address: PATENT COUNSEL, APPLIED MATERIALS, INC., Legal Affairs Department, P.O.BOX 450A, Santa Clara, CA, 95052, US

(73) Assignee: Applied Materials, Inc.

(21) Appl. No.: 10/245,442

(22) Filed: Sep. 16, 2002

(51) Int. Cl. C23C 16/00

(52) U.S. Cl. 427/535; 427/255.28

(57) ABSTRACT

A method for processing a substrate. The method includes introducing one or more precursors into a chemical vapor deposition chamber through a gas distribution plate heated by a heating mechanism disposed at a bottom plate of the gas distribution plate, reacting the precursors to deposit a material on a substrate surface, removing the substrate from the chamber, introducing a cleaning gas into the chamber through the gas distribution plate, and reacting the cleaning gas with deposits within the chamber until substantially all the deposits are consumed.

### CROSS-REFERENCE TO RELATED APPLICATIONS

This application is related to U.S. Ser. No. ______ (AMAT/7346) by Tsuei et al. and entitled “HEATED GAS DISTRIBUTION PLATE FOR A PROCESSING CHAMBER”; and U.S. Ser. No. ______ (AMAT 6249) by Cui et al. and entitled “CHAMBER CLEANING METHOD USING REMOTE AND IN SITU PLASMA CLEANING SYSTEMS.”

### BACKGROUND OF THE INVENTION

1. Field of the Invention

Embodiments of the present invention generally relate to methods for operating a chemical vapor deposition chamber, and more specifically, methods for cleaning the chemical vapor deposition chamber.

2. Description of the Related Art

In the fabrication of integrated circuits and semiconductor devices, materials, such as oxides, are typically deposited on a substrate in a process chamber, such as a chemical vapor deposition (CVD) chamber. The deposition processes typically result in deposition of some of the materials on the walls and components of the deposition chamber, such as the gas distribution plate or faceplate. Since the materials are distributed through the gas distribution plate during processing, a layer of deposition is often formed on the gas distribution plate, which may clog the holes of the plate or flake off in particles that rain down on the substrate, thereby affecting the uniformity of deposition on the substrate and contaminating the substrate. Consequently, it is necessary to clean the interior of the deposition chamber on a regular basis.

Several methods of cleaning the deposition chamber, including the gas distribution plate, have been developed. For example, a remote plasma cleaning procedure may be employed in which an etchant plasma is generated remote from the deposition chamber by a high density plasma source such as a microwave plasma system, toroidal plasma generator or similar device. Dissociated species from the etchant plasma are then transported to the deposition chamber where they can react with and etch away the undesired deposition build up. It is also common to remove the unwanted deposition material that builds up on the interior of chamber walls with an in situ chamber clean operation. Common chamber cleaning techniques include the use of an etchant gas, such as fluorine, to remove the deposited material from the chamber walls and other areas. The etchant gas is introduced into the chamber and plasma is formed so that the etchant gas reacts with and removes the deposited material from the chamber walls.

Conventional chamber cleaning methods, however, still require a considerable amount of time. The longer it takes to clean the chamber, the lower the number of substrates that can be processed in a given time (i.e., throughput) and the more gas that is consumed to clean the chamber.

Therefore, a need exists for an improved method for cleaning a deposition chamber.

### SUMMARY OF THE INVENTION

Embodiments of the present invention are generally directed to a method for processing a substrate. In one embodiment, the method includes introducing one or more precursors into a chemical vapor deposition chamber through a gas distribution plate heated by a heating mechanism disposed at a bottom plate of the gas distribution plate, and reacting the precursors to deposit a material on a substrate surface.

In another embodiment, the present invention is directed to a method for cleaning a chemical vapor deposition chamber, which includes introducing a cleaning gas into the chamber through a gas distribution plate heated by a heating mechanism disposed at a bottom plate of the gas distribution plate, forming a plasma within the chamber, and reacting the cleaning gas with deposits within the chamber until substantially all the deposits are consumed.

In yet another embodiment, the invention is directed to a method for cleaning a chemical vapor deposition chamber, which includes introducing a cleaning gas into a remote plasma source connected to the chamber, striking a plasma in the remote plasma source to form a reactive species, importing the reactive species into the chamber through a gas distribution plate heated by a heating mechanism disposed at a bottom plate of the gas distribution plate, and using the reactive species to clean the chamber.

In still another embodiment, the invention is directed to a method for processing a substrate. The method includes introducing one or more precursors into a chemical vapor deposition chamber through a gas distribution plate heated by a heating mechanism disposed at a bottom plate of the gas distribution plate, reacting the precursors to deposit a material on a substrate surface, removing the substrate from the chamber, introducing a cleaning gas into the chamber through the gas distribution plate, and reacting the cleaning gas with deposits within the chamber until substantially all the deposits are consumed.

### BRIEF DESCRIPTION OF THE DRAWINGS

So that the manner in which the above recited features of the present invention, and other features contemplated and claimed herein, are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional view of a CVD chamber in accordance with various embodiments of the invention shown in FIGS. 3A-5C;

FIG. 2 is an exploded view of the gas distribution assembly in accordance with various embodiments of the invention shown in FIGS. 3A-5C;

FIG. 3A illustrates a partial schematic cross-sectional view of a gas distribution plate in accordance with an embodiment of the invention;

FIG. 3B illustrates a schematic perspective view of a high temperature heat exchanger fluid channel in accordance with an embodiment of the invention;

FIG. 4A illustrates a partial schematic cross-sectional view of a gas distribution plate in accordance with an embodiment of the invention;

FIG. 4B illustrates a cross-sectional view of a heating element in accordance with an embodiment of the invention;

FIGS. 5A-C illustrate partial cross-sectional views of the gas distribution assembly in accordance with various embodiments of the invention;

FIG. 6 is a graph illustrating the effect on the clean rate and the deposition rate as the temperature of the gas distribution plate increases in accordance with an embodiment of the invention;

FIG. 7 illustrates a flow chart of a process for processing a substrate in accordance with an embodiment of the invention;

FIG. 8 illustrates a flow chart of a process for cleaning a CVD chamber in accordance with an embodiment of the invention; and

FIG. 9 illustrates a flow chart of a process for cleaning a CVD chamber in accordance with another embodiment of the invention.

### DETAILED DESCRIPTION OF THE PREFERRED EMBODIMENT

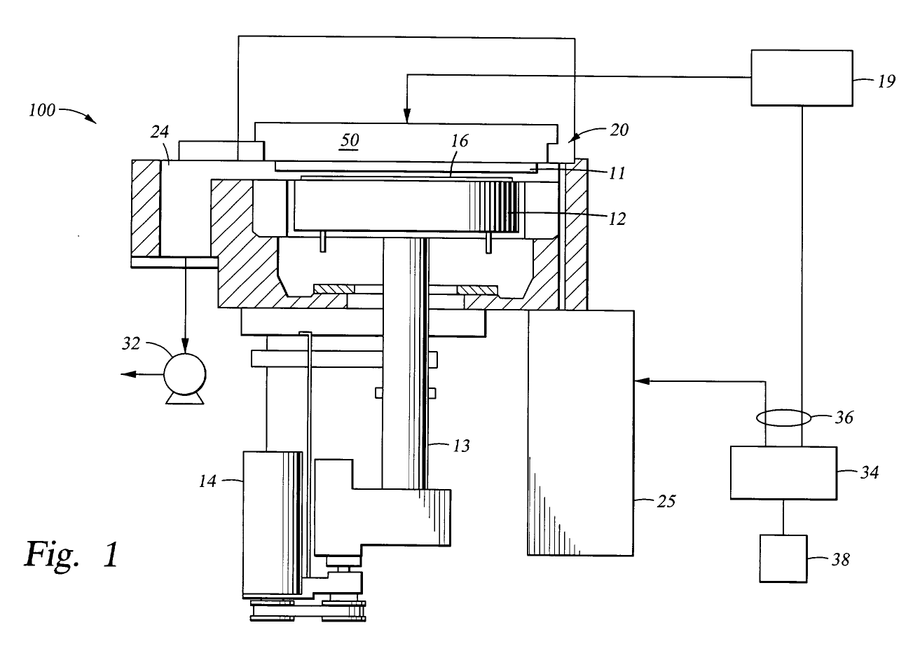

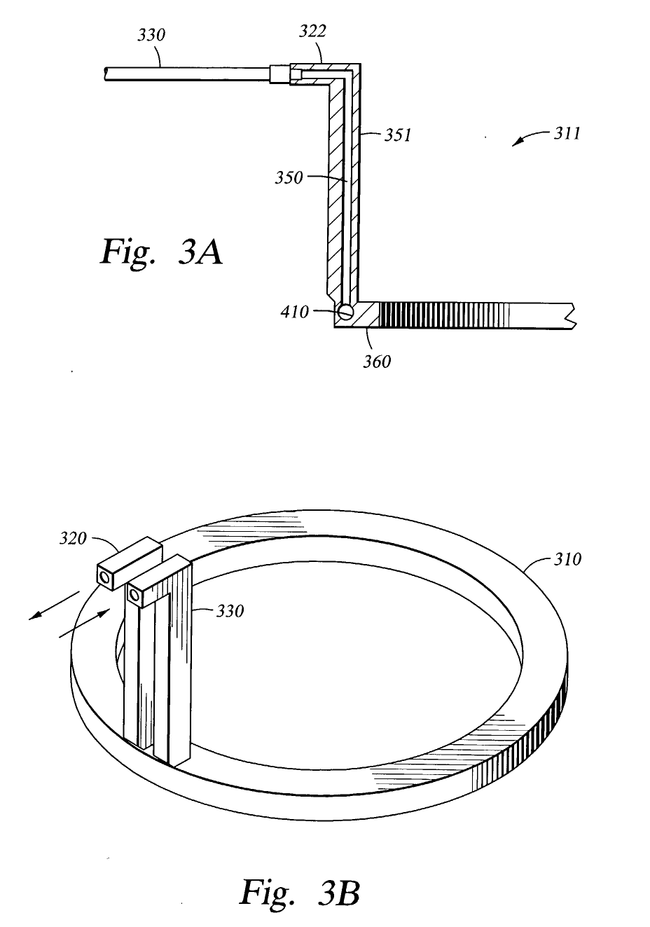

FIG. 1 illustrates a cross-sectional view of a CVD chamber 100 in accordance with various embodiments of the invention shown in FIGS. 3A-5C. The chamber 100 includes a gas distribution assembly 20, which includes a gas box 50 connected to a gas distribution plate or faceplate 11. The gas box 50 is typically water-cooled to a temperature of approximately below 100 degrees Celsius. A substrate support pedestal 12 is disposed below the gas distribution plate 11 so as to define a processing region therebetween for processing a substrate 16. The substrate support pedestal 12 is generally heated by a heater (not shown) at approximately 100 degrees Celsius to 600 degrees Celsius. As a result, the bottom surface of the gas distribution plate 11 is heated by radiation from the heater and/or the plasma, while the top surface of the gas distribution plate 11 is cooled from being in contact with the gas box 50. The gas box 50 supplies processing gases into the chamber 100 through inlets or holes (not shown) in the gas distribution plate 11 so that the gases may be uniformly distributed across the processing region. The processing gases are exhausted through a port 24 by a vacuum pump system 32.

The substrate support pedestal 12 is mounted on a support stem 13 so that the substrate support pedestal 12 can be controllably moved by a lift motor 14 between a lower (loading/off-loading) position and an upper (processing) position. Motors and optical sensors can be used to move and determine the position of movable mechanical assemblies, such as, the throttle valve of the vacuum pump 32 and the motor for positioning the substrate support pedestal 12.

A thermal or plasma enhanced process may be performed in the chamber 100. In a plasma process, a controlled plasma can be formed adjacent to the substrate 16 by applying RF energy to the gas distribution plate 11 from RF power supply 25 with the substrate support pedestal 12 grounded. An RF power supply 25 can supply either a single or mixed frequency RF power to the gas distribution plate 11 to enhance the decomposition of any reactive species introduced into the chamber 100. A mixed frequency RF power supply typically supplies power at a high RF frequency of about 13.56 MHz and at a low RF frequency of about 350 kHz.

A system controller 34 controls the motor 14, the gas mixing system 19, and the RF power supply 25 over control lines 36. The system controller 34 may also control analog assemblies, such as mass flow controllers and RF generators. The system controller 34 controls the activities of the CVD processing chamber 100 and executes system control software stored in a memory 38, which may be a hard disk drive, a floppy disk drive, and a card rack. The controller 34 may be one of any form of general purpose computer processor (CPU) that can be used in an industrial setting for controlling various chambers and sub-processors. Various support circuits may be coupled to the CPU for supporting the processor in a conventional manner.

Software routines may be stored in the memory 38 or executed by a second CPU that is remotely located. The software routines are generally executed to perform process recipes or sequences and to dictate the timing, mixture of gases, RF power levels, substrate support pedestal position, and other parameters of a particular process. The software routines, when executed, transform the general purpose computer into a specific process computer that controls the chamber operation so that a chamber process is performed. Alternatively, the software routines may be performed in a piece of hardware as an application specific integrated circuit or a combination of software or hardware. Other details of the CVD processing chamber 100 may be described in U.S. Pat. No. 5,000,113, entitled “A Thermal CVD/PECVD Processing chamber and Use for Thermal Chemical Vapor Deposition of Silicon Dioxide and In-situ Multi-step Planarized Process”, issued to Wang et al., and assigned to Applied Materials, Inc., the assignee of the invention, and is incorporated by reference herein to the extent not inconsistent with the invention.

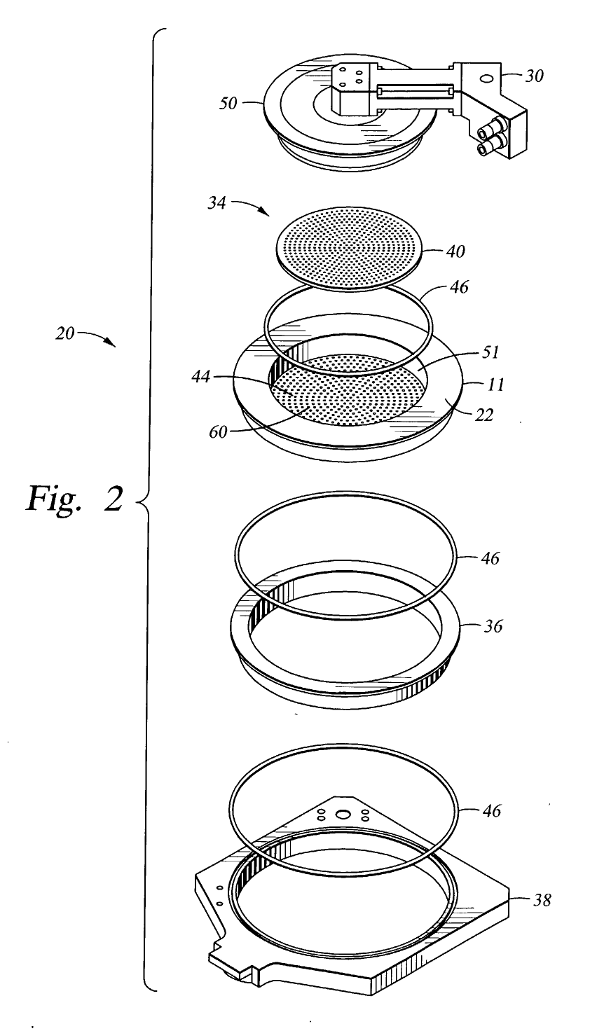

FIG. 2 illustrates an exploded view of the gas distribution assembly 20 in accordance with various embodiments of the invention shown in FIGS. 3A-5C. The gas distribution assembly 20 includes a gas manifold 30, the gas box 50 (or gas injection cover plate), a showerhead assembly 34, and an isolator 36, all of which are mounted on an electrically grounded chamber lid 38. The isolator 36 is generally composed of a non-conductor material to isolate RF power from the grounded chamber lid 38. The showerhead assembly 34 includes a perforated blocker plate 40 and the gas distribution plate 11. The blocker plate 40 is generally a flat circular member having a plurality of holes. The gas distribution plate 11 is a dish-shaped device having a circular, centrally disposed cavity defined by a side wall 51 and a bottom plate 60 through which are formed a plurality of holes 44. The blocker plate 40 and the gas distribution plate 11 are configured to provide a uniform distribution of gases over the substrate surface through their respective holes. An annular flange portion 22 of the gas distribution plate 11 projects outwardly in a horizontal plane from the upper portion of the gas distribution plate 11. The flange portion 22 serves to provide engagement of the gas distribution plate 11 with the gas box 50. A cavity between the blocker plate 40 and the gas box 50 also serves as an additional agitation stage to continue mixing the process gases. O-rings 46 are disposed between the various components to help ensure hermetic seals to prevent leakage of the gases.

FIG. 3A illustrates a partial schematic cross-sectional view of a gas distribution plate 311 in accordance with one embodiment of the invention. The gas distribution plate 311 includes a flange portion 322, a side wall 351 and a bottom plate 360. A channel 310 is disposed inside the bottom plate 360 for containing fluid, such as, a high temperature heat exchanger fluid 350. Other types of fluid that may heat the gas distribution plate 311 are also contemplated by the invention. The channel 310 may be disposed circumferentially around the perimeter of the bottom plate 360. In one embodiment, the channel 310 is disposed on the same level as the plurality of holes (not shown) disposed through the bottom plate 360. In this manner, the high temperature heat exchanger fluid 350 is configured to provide heating throughout the gas distribution plate 311. The heat exchanger fluid 350 may be provided by a heat exchanger system (not shown) at high temperatures sufficient to heat the gas distribution plate 311 to a temperature of greater than approximately 100 degrees Celsius. The channel 310 may also include an inlet 320 and an outlet 330 for the fluid, which are disposed inside the flange portion 322 and the side wall 351 on one side of the gas distribution plate 311, as shown in FIG. 3B. The inlet 320 and the outlet 330 may be made from a polyamide composition material, such as Vespel® by Dupont of Newark, Del. In this manner, the inlet 320 and the outlet 330 may serve as RF insulators, insulating the high temperature heat exchanger fluid 350 from the outside environment.

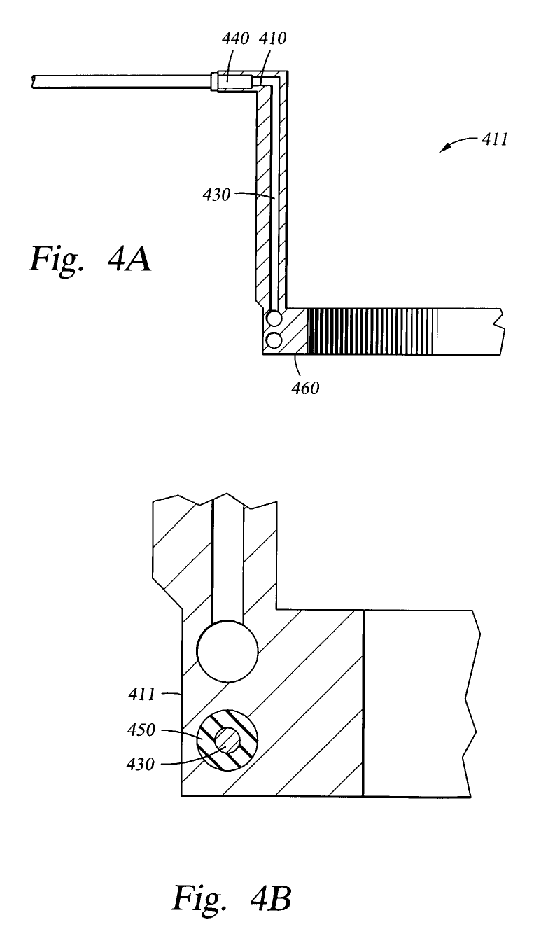

Another embodiment in which the gas distribution plate may be heated is illustrated in FIG. 4A. In this embodiment, the gas distribution plate 411 includes a channel 410 disposed inside a bottom plate 460 for containing a heating element 430. In another embodiment, the heating element 430 may be cast in place in a molded or otherwise fabricated gas distribution plate 411. The heating element 430 may be disposed circumferentially around the perimeter of the bottom plate 460. The heating element 430 may be disposed on the same level as the plurality of holes (not shown) disposed through the bottom plate 460. In this manner, the heating element is configured to electrically provide heating around the gas distribution plate 411. In one example, the heating element 430 is configured to heat the gas distribution plate 411 to a temperature of greater than approximately 100 degrees Celsius. FIG. 4B illustrates that the heating element 430 may be insulated with RF insulating material 450, such as, magnesium oxide, fiber glass or nylon, which may be available from Watlow Electric Manufacturing Company of St. Louis, Mo. An adapter 440 may be connected to the heating element 430 to reduce the potential danger from the RF hot material extruding out of the gas distribution plate 411. The adapter 440 may also protect the o-ring (not shown) disposed between the gas distribution plate 411 and the gas box (not shown) since the temperature of the adapter 440 is significantly lower than the temperature of the heating element 430.

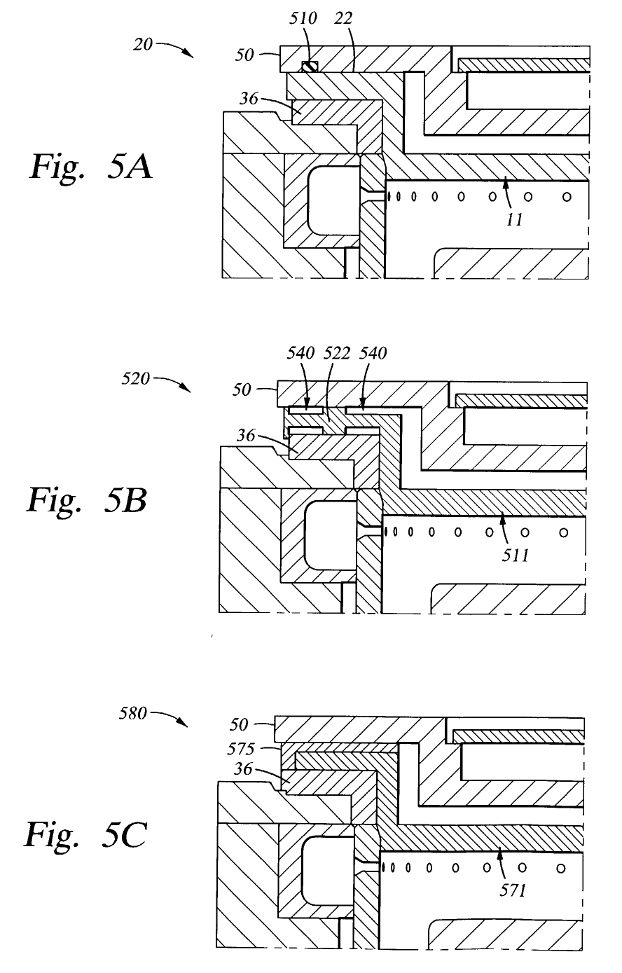

The heated gas distribution plate in accordance with various embodiments of the invention may be enhanced by the gas distribution assembly 20 illustrated in FIGS. 5A-C. FIG. 5A illustrates a partial cross-sectional view of the gas distribution assembly 20 in accordance with one embodiment of the invention. The flange portion 22 of the gas distribution plate 11 is in contact with the gas box 50. Typically, a soft RF gasket is disposed between the flange portion 22 and the gas box 50. In accordance with this embodiment of the invention, a hard RF gasket 510 is disposed between the flange portion 22 and the gas box 50 to reduce the contact area between the gas distribution plate 11 and the gas box 50. The hard RF gasket 510, in effect, increases the distance or space between the flange portion 22 and the gas box 50. In this manner, heat transfer/loss from the gas distribution plate 11 may be minimized.

Another embodiment in which heat transfer may be minimized from the gas distribution plate is illustrated in FIG. 5B. In this embodiment, the gas assembly 520 includes a gas distribution plate 511, which has a flange portion 522 in contact with a gas box 50. The flange portion 522 defines recesses or grooves 540, which provides a distance between the flange portion 522 and the gas box 50 or the isolator 36. In this manner, the recesses 540 are designed to reduce the contact area between the gas box 50 and the flange portion 522, thereby minimizing heat transfer from the gas distribution plate 511.

Yet another embodiment in which heat transfer may be minimized from the gas distribution plate is illustrated in FIG. 5C. In this embodiment, a thermal isolator 575 is disposed between a gas distribution plate 571 and the gas box 50. The thermal isolator 575 may be made from any material, such as ceramic, that provides thermal insulation between the gas distribution plate 571 and the gas box 50. By disposing the thermal isolator 575 between the gas distribution plate 571 and the gas box 50, the gas distribution plate 571 is in contact with the gas box 50 only through the thermal isolator 575. The thermal isolator 575, therefore, works to minimize heat transfer from the gas distribution plate 571.

Other means for minimizing heat transfer from the gas distribution plate to the gas box 50 are also contemplated by the invention. For instance, the o-rings 46 between the gas distribution plate and the gas box 50 may be positioned closer toward the periphery of the gas distribution plate and the gas box 50 so as to increase the space between the two components.

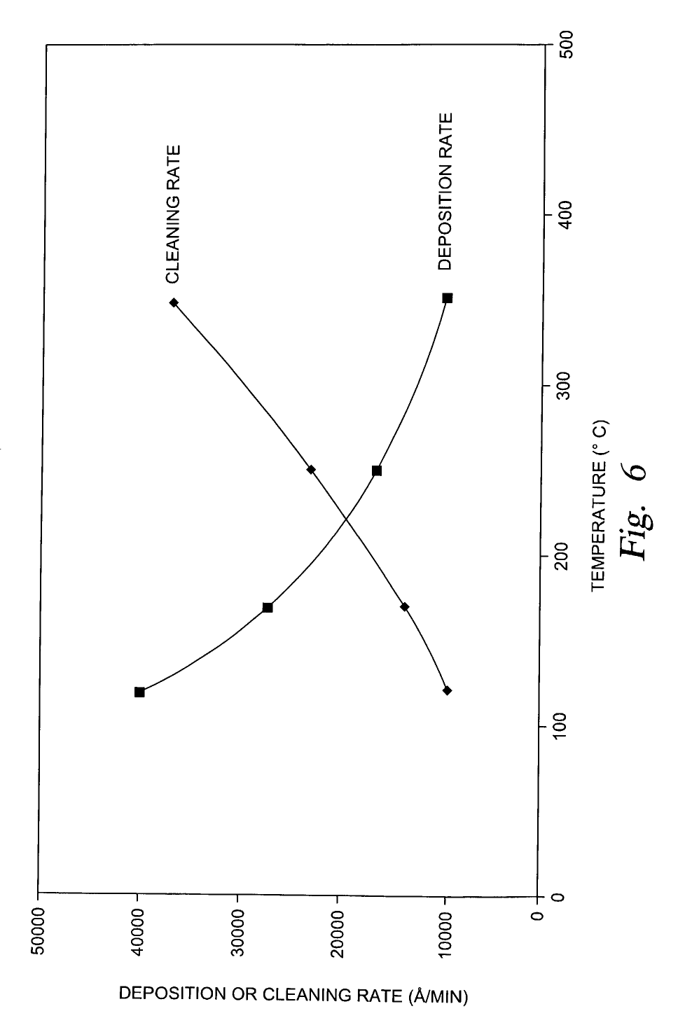

Recently, it has been observed (as shown in FIG. 6) that at low temperatures, the deposition rate on a gas distribution plate during processing is much higher than at high temperatures and the etch rate on the gas distribution plate during cleaning is much lower than at high temperatures. Accordingly, it is desirable to operate the gas distribution plate at high temperatures, particularly during processing and cleaning. By operating the gas distribution plate at high temperatures, the deposition rate on the gas distribution plate during processing is minimized, while the clean rate is maximized, thereby reducing the chamber cleaning period. By reducing the chamber cleaning period, the mean number of substrates between maintenance is increased. Furthermore, since less film is being deposited on the gas distribution plate during processing, more precursors are available to be deposited on the substrate, thereby resulting in an increased deposition rate on the substrate. Additional benefits to using a heated gas distribution plate during processing also include a reduction of dielectric constant in the deposited film on the substrate and a reduction of particle contamination on the substrate.

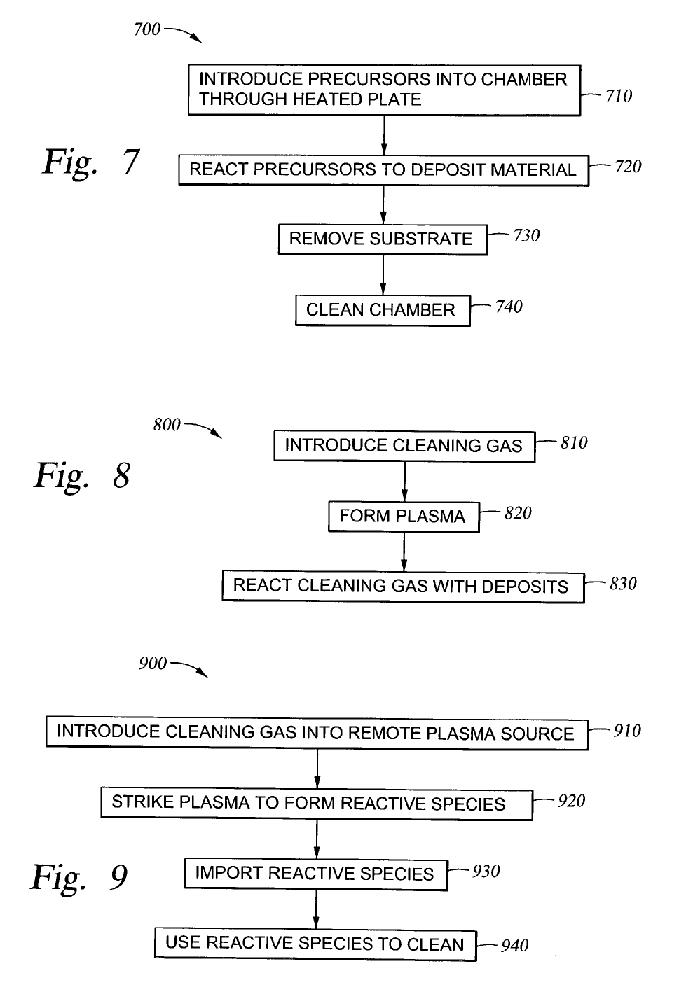

FIG. 7 illustrates a process 700 for processing a substrate in the CVD chamber 100 in accordance with an embodiment of the invention. At step 710, one or more precursors are introduced into the CVD chamber 100. The precursors are introduced through a gas distribution plate heated by a heating mechanism, such as the high temperature heat exchanger fluid 350, which was described with reference to FIGS. 3A and B, or the heating element 430, which was described with reference to FIGS. 4A and B. In one embodiment, the gas distribution plate is heated at all times, such as, during processing, cleaning and even during status or idle state. Other heating mechanisms capable of heating the gas distribution plate to a temperature of greater than approximately 100 Celsius are also contemplated by the invention. At step 720, the precursors are reacted to deposit a material on the substrate surface. At step 730, the substrate is removed from the chamber 100. At step 740, the chamber 100 is cleaned. FIGS. 8 and 9 describe various methods of cleaning the chamber 100.

FIG. 8 illustrates a process 800 of cleaning a CVD chamber in accordance with one embodiment of the invention. At step 810, a cleaning gas, such as fluorine, is introduced into the CVD chamber 100 through the heated gas distribution plate. At step 820, a plasma is formed within the chamber 100. The plasma may be formed by applying an electric field to the cleaning gas. Typically, the electric field is generated by connecting the substrate support pedestal 12 to a source of radio frequency (RF) power. Alternatively, the RF power source may be coupled to the gas distribution plate 11, or to both the gas distribution plate 11 and the substrate support pedestal 12. At step 830, the cleaning gas reacts with deposits within the chamber 100 until the deposits are consumed.

FIG. 9 illustrates a process 900 of cleaning a CVD chamber in accordance with another embodiment of the invention. At step 910, a cleaning gas is introduced into a remote plasma source (not shown), which is connected to the chamber 100. The remote plasma source is generally configured to provide a remotely generated plasma to the chamber 100. At step 920, a remote plasma is generated by applying an electrical field to the cleaning gas in the remote plasma source (not shown), forming a plasma of reactive species. At step 930, the reactive species generated in the remote plasma source are imported into the chamber 100 through the heated gas distribution plate. At step 940, the reactive species are used to clean the chamber 100.

While the foregoing is directed to embodiments of the present invention, other and further embodiments of the invention may be devised without departing from the basic scope thereof, and the scope thereof is determined by the claims that follow.

1. A method for processing a substrate, comprising:
introducing one or more precursors into a chemical vapor deposition chamber through a gas distribution plate heated by a heating mechanism disposed at a bottom plate of the gas distribution plate; and
reacting the precursors to deposit a material on a substrate surface.

2. The method of claim 1, further comprising:
removing the substrate from the chamber; and
cleaning the chamber.

3. The method of claim 2, wherein cleaning the chamber comprises:
introducing a cleaning gas into the chamber through the heated gas distribution plate;
forming a plasma within the chamber;
reacting the cleaning gas with deposits within the chamber until substantially all the deposits are consumed.

4. The method of claim 2, wherein cleaning the chamber comprises:
introducing a cleaning gas into a remote plasma source connected to the chamber;
striking a plasma in the remote plasma source to form a reactive species;
transporting the reactive species from the remote plasma source into the chamber; and
using the reactive species to clean the chamber.

5. The method of claim 1, further comprising:
introducing a processing gas into the chamber through the heated gas distribution plate; and
forming a plasma of the precursors and the processing gas inside the chamber.

6. The method of claim 1, wherein the heating mechanism is one of a heating element and a high temperature heat exchanger fluid.

7. The method of claim 6, wherein the heat exchanger fluid is heated by a heat source.

8. The method of claim 1, wherein the heating mechanism is disposed circumferentially around the bottom plate of the gas distribution plate.

9. The method of claim 1, wherein the bottom plate defines a plurality of holes for transmitting the precursors, and wherein the heating mechanism is disposed circumferentially around the plurality of holes.

10. The method of claim 1, wherein the heating mechanism is contained in a channel defined around the bottom plate.

11. The method of claim 10, wherein the channel is defined around a plurality of holes disposed through the bottom plate.

12. The method of claim 1, wherein the heating mechanism is configured to heat the distribution plate to a temperature greater than approximately 100 degrees Celsius.

13. A method for cleaning a chemical vapor deposition chamber, comprising:
introducing a cleaning gas into the chamber through a gas distribution plate heated by a heating mechanism disposed at a bottom plate of the gas distribution plate;
forming a plasma within the chamber; and
reacting the cleaning gas with deposits within the chamber until substantially all the deposits are consumed.

14. The method of claim 13, wherein the heating mechanism is one of a heating element and a high temperature heat exchanger fluid.

15. The method of claim 14, wherein the heat exchanger fluid is heated by a heat source.

16. The method of claim 13, wherein the heating mechanism is disposed circumferentially around the bottom plate of the gas distribution plate.

17. The method of claim 13, wherein the bottom plate defines a plurality of holes for transmitting the precursors, and wherein the heating mechanism is disposed circumferentially around the plurality of holes.

18. The method of claim 13, wherein the heating mechanism is contained in a channel defined around the bottom plate.

19. The method of claim 18, wherein the channel is defined around a plurality of holes disposed through the bottom plate.

20. The method of claim 13, wherein the heating mechanism is configured to heat the distribution plate to a temperature greater than approximately 100 degrees Celsius.

21. A method for cleaning a chemical vapor deposition chamber, comprising:
introducing a cleaning gas into a remote plasma source connected to the chamber;
striking a plasma in the remote plasma source to form a reactive species;
importing the reactive species into the chamber through a gas distribution plate heated by a heating mechanism disposed at a bottom plate of the gas distribution plate; and
using the reactive species to clean the chamber.

22. The method of claim 21, wherein the heating mechanism is one of a heating element and a high temperature heat exchanger fluid.

23. The method of claim 22, wherein the heat exchanger fluid is heated by a heat source.

24. The method of claim 21, wherein the heating mechanism is disposed circumferentially around the bottom plate of the gas distribution plate.

25. The method of claim 21, wherein the bottom plate defines a plurality of holes for transmitting the precursors, and wherein the heating mechanism is disposed circumferentially around the plurality of holes.

26. The method of claim 21, wherein the heating mechanism is contained in a channel defined around the bottom plate.

27. The method of claim 26, wherein the channel is defined around a plurality of holes disposed through the bottom plate.

28. The method of claim 21, wherein the heating mechanism is configured to heat the distribution plate to a temperature greater than approximately 100 degrees Celsius.

29. A method for processing a substrate, comprising:
introducing one or more precursors into a chemical vapor deposition chamber through a gas distribution plate heated by a heating mechanism disposed at a bottom plate of the gas distribution plate;
reacting the precursors to deposit a material on a substrate surface;
removing the substrate from the chamber;
introducing a cleaning gas into the chamber through the gas distribution plate; and
reacting the cleaning gas with deposits within the chamber until substantially all the deposits are consumed.

30. The method of claim 29, wherein the heating mechanism is one of a heating element and a high temperature heat exchanger fluid.

31. The method of claim 30, wherein the heat exchanger fluid is heated by a heat source.

32. The method of claim 29, wherein the heating mechanism is disposed circumferentially around the bottom plate of the gas distribution plate.

33. The method of claim 29, wherein the bottom plate defines a plurality of holes for transmitting the precursors, and wherein the heating mechanism is disposed circumferentially around the plurality of holes.

34. The method of claim 29, wherein the heating mechanism is contained in a channel defined around the bottom plate.

35. The method of claim 34, wherein the channel is defined around a plurality of holes disposed through the bottom plate.

36. The method of claim 29, wherein the heating mechanism is configured to heat the distribution plate to a temperature greater than approximately 100 degrees Celsius.
